(19) United States
(12) Patent Application Publication
(10) Pub. No.: US 2005/0258426 A1
(43) Pub. Date: Nov. 24, 2005

(54) Organic light emitting display device

(76) Inventor: Hyun-Eok Shin, Gunpo-si (KR)

Correspondence Address: MCGUIREWOODS, LLP, 1750 TYSONS BLVD, SUITE 1800, MCLEAN, VA, 22102, US

(21) Appl. No.: 11/125,108

(22) Filed: May 10, 2005

(30) Foreign Application Priority Data
May 11, 2004 (KR) 2004-33221

(51) Int. Cl. G02F 1/1333

(52) U.S. Cl. 257/72

(57) ABSTRACT

An organic light emitting display device may be capable of preventing galvanic reaction from occurring between source and drain electrodes and a pixel electrode, and preventing a voltage drop of a metal wiring. The organic light emitting display device can include an active layer formed on a substrate; a gate electrode formed on a gate insulating layer; a metal wiring formed on an interlayer insulating layer, and source and drain electrodes electrically connected to the source and drain regions via contact holes; and a pixel electrode electrically connected to any one of the source and drain electrodes. The source and drain electrodes and the metal wiring are formed of materials having low resistance and an oxidation-reduction potential (Redox potential) difference of about 0.3 or less with respect to the pixel electrode.

CROSS-REFERENCE TO RELATED APPLICATION

This application claims priority to and the benefit of Korean Patent Application No. 2004-33221, filed May. 11, 2004, which is incorporated herein by reference in its entirety.

### BACKGROUND OF THE INVENTION

1. Field of the Invention

The present invention relates to an organic light emitting display device, and more particularly, to an organic light emitting display device capable of preventing galvanic reaction from occurring between source and drain electrodes and a pixel electrode, and preventing voltage drop of a metal wiring.

2. Description of the Related Art

Galvanic effect happens when two metals are proximate. When two metals are close enough, voltage is generated and current flows because of an oxidation-reduction potential difference between the two different kinds of metals. Among such different metals in electrical contact, the highly active (low potential) metal acts as an anode and the relatively lower active (high potential) metal acts as a cathode due to a difference in work function at an interface between the two metals.

The potential difference between the two metals may cause corrosion at the two metals when the two metals are exposed to a corrosive solution. This may be referred to as galvanic corrosion, wherein the highly active anode corrodes at a faster rate compared to a sole anode while the lower active cathode corrodes at a lower rate.

Generally, an organic light emitting display device is a light emitting display device that emits light when electrons and holes are injected from an electron injection electrode (cathode) and a hole injection electrode (anode) to an emission layer and excitons created by recombination of the injected electrons and holes transition from an excited state to a base state.

The use of this principle eliminates the need for a separate light source that was necessary in a conventional thin film liquid crystal display device, thereby reducing the volume and weight of the device.

The organic light emitting display device may be either a passive matrix organic light emitting display device or an active matrix organic light emitting display device, depending on how it is driven.

The passive matrix organic light emitting display device is easy to manufacture because of its simple configuration. However, the passive matrix organic light emitting display device has high power consumption and a difficulty in implementing a large-sized display device. Further, the aperture ratio degrades as the number of wirings increases.

Accordingly, passive matrix organic light emitting display devices are typically used in small-sized display devices while active matrix organic light emitting display devices are typically used in large-sized display devices.

Meanwhile, in the organic light emitting display device, there may arise a problem of voltage drop (IR drop) in source and drain electrodes and a metal wiring because metals such as molybdenum (Mo), molybdenum tungsten (MoW), and the like typically used for the source and drain electrodes and the metal wiring have high resistance.

A method in which an aluminum (Al) metal having small resistance is used as the source and drain electrodes and the metal wiring has been introduced to solve the foregoing problem.

Pure Al has an oxidation-reduction potential (i.e., Redox Potential) of about −1.64. Aluminum neodymium (AlNd) alloy has an oxidation-reduction potential of about −1.58. However, indium tin oxide (ITO) (which is the most commonly used pixel electrode material), has a very large oxidation-reduction potential difference with respect to the Al—its oxidation-reduction potential is about −0.82.

As described above, a galvanic reaction occurs between materials having a large difference in the oxidation-reduction potential (i.e., redox potential). This galvanic reaction can cause interface contact defects. Accordingly, the organic light emitting display device may not work.

In order to solve the problem that arise when the Al or AlNd is used in the source and drain electrodes and the metal wiring, an Al layer can be formed as the source and drain electrodes and the metal wiring, and a metal such as Mo (having an oxidation-reduction potential of about −0.51), MoW, or the like can be deposited in a thin thickness on the Al layer to form a galvanic reaction barrier layer, wherein the Mo has a oxidation-reduction potential difference of about 0.31 with respect to ITO.

However, the method of forming the galvanic reaction barrier layer such as Mo or MoW on the Al layer is accompanied by additional processes, resulting in production cost increase.

### SUMMARY OF THE INVENTION

The present invention, therefore, provides an organic light emitting display device that may be capable of preventing voltage drop (e.g. IR drop) and galvanic reaction from occurring at an interface between source and drain electrodes and a pixel electrode. This may be accomplished by forming the source and drain electrodes and a metal wiring using materials having small resistance and a small oxidation-reduction potential difference with respect to the pixel electrode material.

An organic light emitting display device can include an active layer having source and drain regions, formed on a substrate; a gate electrode formed on a gate insulating layer, a metal wiring formed on an interlayer insulating layer; and source and drain electrodes electrically connected to the source and drain regions via contact holes. A pixel electrode may be electrically connected to any one of the source and drain electrodes. A pixel defining layer may have an opening to expose a portion of the pixel electrode. An organic layer may be formed on the opening. An upper electrode may be formed on an entire surface of the substrate. The source and drain electrodes and the metal wiring may be formed of materials having small resistance and an oxidation-reduction potential (i.e., Redox potential) difference of about 0.3 or less with respect to the pixel electrode.

The source and drain electrodes and the metal wiring may be Al—Ni alloys. For example, the source and drain electrodes and the metal wiring may be formed of Al—Ni alloys containing nickel (Ni) of about 10% or less.

The pixel electrode may be formed of, for example, indium tin oxide (ITO) or indium zinc oxide (IZO).

It is preferable that the organic layer comprises an emission layer (EML), and at least one of a hole injecting layer (HIL), a hole transporting layer (HTL), a hole blocking layer (HBL), an electron transporting layer (ETL), or an electron injecting layer (EIL).

### BRIEF DESCRIPTION OF THE DRAWINGS

FIGS. 1A, 1B, 1C, and 1D are process cross-sectional views illustrating an organic light emitting display device according to an embodiment of the present invention.

### DETAILED DESCRIPTION

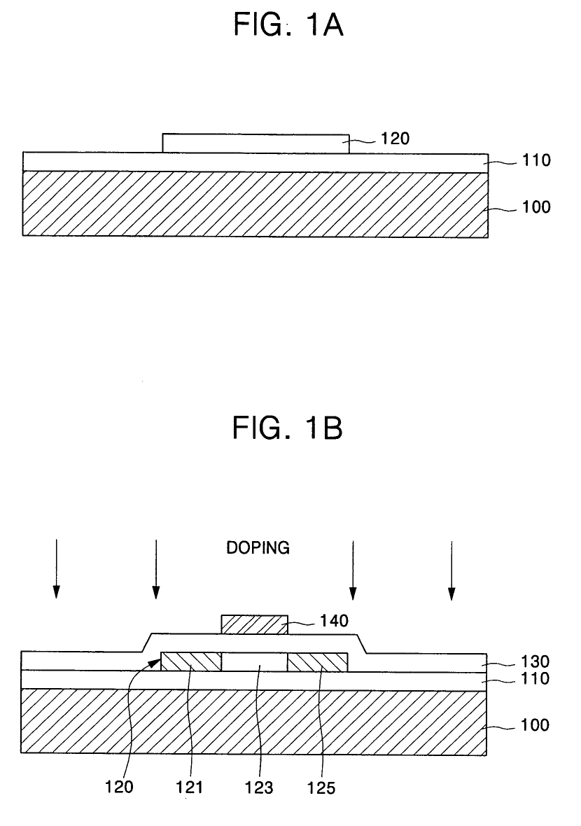

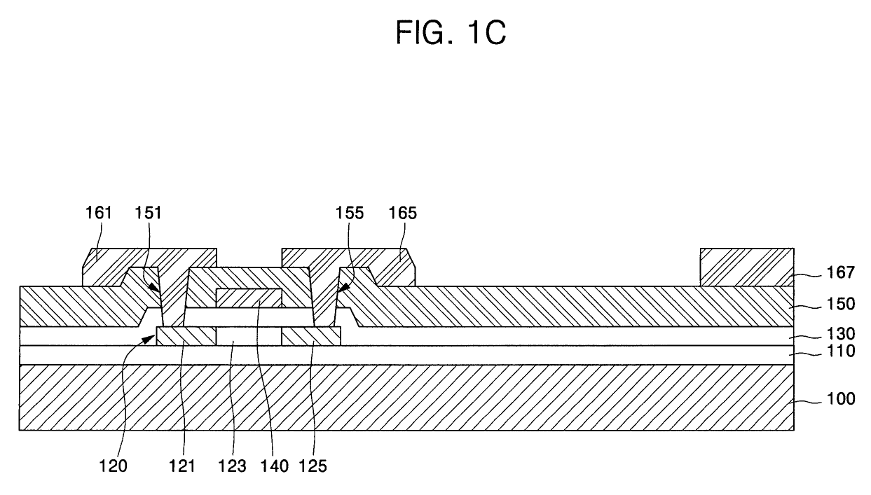

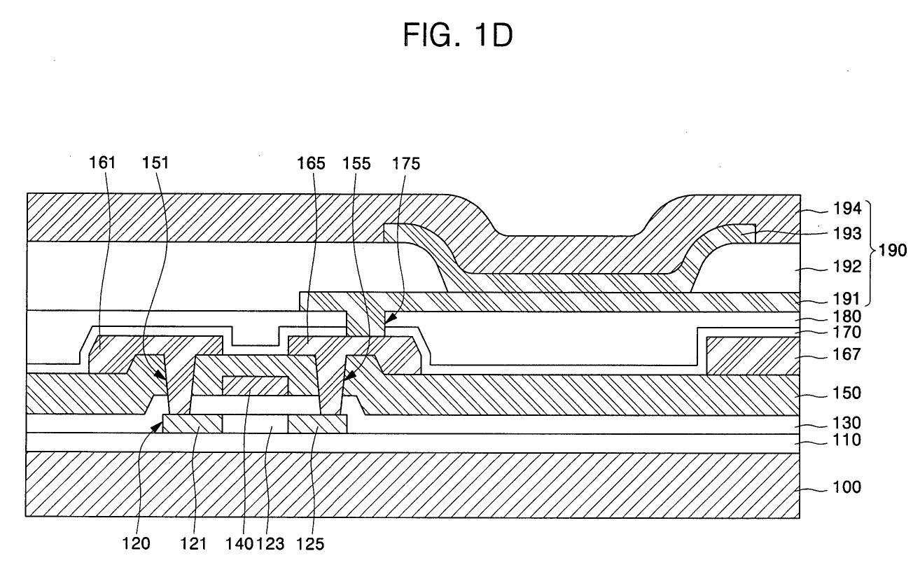

As shown in FIG. 1A, a buffer layer 110 (or diffusion barrier) may be deposited on a substrate 100 using plasma-enhanced chemical vapor deposition (PECVD), low pressure chemical vapor deposition (LPCVD), sputtering, or the like. This may be done to prevent impurities such as metal ions from the substrate 100 from diffusing and penetrating into an active layer (polycrystalline silicon).

The substrate 100 may be a suitable substrate such as a glass or plastic substrate.

After the buffer layer 110 is formed, an amorphous silicon (amorphous Si) layer may be deposited on the buffer layer 110 using PECVD, LPCVD, sputtering, or the like. Dehydrogenation may then be carried out in a vacuum furnace. When the amorphous silicon layer is deposited by LPCVD or sputtering, dehydrogenation may not be required.

The amorphous silicon may be crystallized to form a polycrystalline silicon (poly-Si) layer through a crystallization process of the amorphous silicon in which the amorphous silicon layer is irradiated with high energy. A crystallization process such as excimer laser annealing (ELA), metal induced crystallization (MIC), metal induced lateral crystallization (MILC), sequential lateral solidification (SLS), solid phase crystallization (SPC), or the like may be used as the crystallization process.

After the polycrystalline silicon layer is formed, photoresist for forming an active layer on the polycrystalline silicon layer is formed. The polycrystalline silicon layer may be patterned using the photoresist as a mask to form an active layer 120.

As shown in FIG. 1B, a gate insulating layer 130 may be deposited on the active layer 120, a gate metal may be deposited on the gate insulating layer 130, and then the gate metal may be patterned to form a gate electrode 140.

After the gate electrode 140 is formed, the active layer 120 may be doped with an impurity having a predetermined conductivity type using the gate electrode 140 as a mask to form source and drain regions 121 and 125. A region between the source and drain regions 121 and 125 in the active layer may act as a channel region 123 of a thin film transistor (TFT).

As shown in FIG. 1C, after the active layer 120 is doped with the impurity to form the source and drain regions 121 and 125, an interlayer insulating layer 150 may be formed on substantially an entire surface of the substrate 100 and may be patterned to form contact holes 151 and 155 that expose portions of the source and drain regions 121 and 125.

Thereafter, a predetermined conductive layer may be deposited on the entire surface of the substrate 100 and may be subjected to photolithography to form source and drain electrodes 161 and 165, which may be electrically connected to the source and drain regions 121 and 125 via the contact holes 151 and 155, and to form a metal wiring 167.

The source and drain electrodes 161 and 165 and the metal wiring 167 may be formed of materials having small resistance, and an oxidation-reduction potential (i.e., Redox Potential) difference of about 0.3 or less with respect to the pixel electrode material to prevent galvanic reaction with the pixel electrode. Al—Ni (“ACX”) may be used for the source and drain electrodes 161 and 165 and the metal wiring 167.

The ACX may be an Al alloy containing Ni of about 10% or less.

The ACX may have a small resistance and an oxidation-reduction potential (Redox Potential) of about −1.02. The ACX may have an oxidation-reduction potential difference of about 0.2 with respect to ITO (which has an oxidation-reduction potential of about −0.82 and is typically used in the pixel electrode).

As shown in FIG. 1D, a passivation layer 170 may be formed on substantially the entire surface of the substrate 100 after the source and drain electrodes 161 and 165 and the metal wiring 167 are formed.

Annealing may be carried out after the passivation layer 170 is formed. The annealing may be intended to cure damage occurring in a TFT manufacturing process and enhance the properties of the thin film transistor.

After the annealing, a planarization layer 180 may be formed to remove steps or other irregularities in the underlying structure. One may use a material capable of relieving and planarizing the curvature of the TFT because of its fluidity such as acryl, polyimide (PI), polyamide (PA), benzocyclobutene (BCB), or the like for the planarization layer 180.

After the planarization layer 180 is formed, a via hole 175 may be formed to expose a portion of any one of the source and drain electrodes 161 and 165 (for this example, drain electrode 165).

An organic light emitting diode 190 may then be formed electrically connected to the drain electrode 165 through the via hole 175.

The organic light emitting diode 190 may include a pixel electrode 191, a pixel defining layer 192 having an opening formed to expose a portion of the pixel electrode 191, an organic emission layer 193 formed on the opening, and a upper electrode 194 formed on the entire surface of the substrate 100.

The pixel electrode 191 may be formed of a transparent conductive material such as indium tin oxide (ITO) or indium zinc oxide (IZO).

The organic emission layer 193 may be formed of several layers depending on its functionality. Generally, it may be formed of a multi-layered structure including at least one of a hole injecting layer (HIL), a hole transporting layer (HTL), a hole blocking layer (HBL), an electron transporting layer (ETL), or an electron injecting layer (EIL). It may also include an emission layer.

The emission layer may be a layer that emits, by itself, light of one or more specific wavelengths by recombination of electrons and holes injected from the cathode and the anode of the organic light emitting diode. The hole injecting layer, the hole transporting layer, the hole blocking layer, the electron transporting layer, the electron injecting layer, and the like having charge transporting capability may be further selectively inserted between each electrode and the emission layer to obtain highly efficient emission.

Although this aspect is not shown, the organic light emitting diode 190 may be subsequently encapsulated using an upper substrate.

With the organic light emitting display device formed by the processes as described above, it may be possible to prevent galvanic reaction between the source and drain electrodes and the pixel electrode without additional processes by using the ACX that is an Al—Ni alloy as a material for the source and drain electrodes 161 and 165 and the metal wiring 167. Further, it may be possible to prevent the voltage drop (IR drop) of the metal wiring by virtue of ACX that has low resistance.

As described above, the present invention may be capable of providing an organic light emitting display device that prevents voltage drop (IR drop) and galvanic reaction from occurring at the interface between the source/drain electrodes and the pixel electrode by forming the source/drain electrodes and the metal wiring using a material having low resistance and a small oxidation-reduction potential difference with respect to the pixel electrode material.

Although the exemplary embodiments of the present invention relate to organic light emitting devices, the invention may be implemented in other devices such as liquid crystal displays and hybrid liquid crystal/organic backlit displays.

Although the present invention has been described with reference to certain exemplary embodiments thereof, changes may be made to the described embodiments without departing from the scope of the present invention.

1. A display device, comprising:
an active layer formed on a substrate and having source and drain regions;
a gate electrode formed on a gate insulating layer;
source and drain electrodes electrically coupled to the source and drain regions via contact holes;
a pixel electrode electrically connected to one of the source and drain electrodes;
a pixel defining layer having an opening exposing a portion of the pixel electrode;
an organic layer formed on the opening; and
an upper electrode formed on substantially an entire surface of the substrate,
wherein the source and drain electrodes comprise materials having low resistance and an oxidation-reduction potential difference of about 0.3 or less with respect to the pixel electrode.

2. The device of claim 1, wherein the source and drain electrodes comprise Al—Ni alloys.

3. The device of claim 1, wherein the source and drain electrodes comprise Al—Ni alloys containing Ni of 10% or less.

4. The device of claim 1, wherein the pixel electrode comprises at least one material selected from a group of indium tin oxide (ITO) and indium zinc oxide (IZO).

5. The device of claim 1, wherein the substrate comprises at least one material selected from a group of glass and plastic.

6. The device of claim 1, wherein the organic layer comprises an emission layer, and at least one layer selected from a group of a hole injecting layer, a hole transporting layer, a hole blocking layer, an electron transporting layer, and an electron injecting layer.

7. The device of claim 1, further comprising metal wiring formed on an insulating interlayer, wherein the metal wiring comprises a material having low resistance and an oxidation-reduction potential difference of about 0.3 or less with respect to the pixel electrode.

8. A method of manufacturing an organic light emitting display device, comprising:
forming an active layer formed with source and drain regions on a substrate;
forming a gate electrode on the gate insulating layer;
forming source and drain electrodes electrically coupled to the source and drain regions via contact holes;
forming a pixel electrode electrically connected to one of the source and drain electrodes;
forming a pixel defining layer having an opening exposing a portion of the pixel electrode;
forming an organic layer on the opening; and
forming an upper electrode on substantially an entire surface of the substrate,
wherein the source and drain electrodes comprise materials having low resistance and an oxidation-reduction potential difference of about 0.3 or less with respect to the pixel electrode.

9. The method of claim 8, wherein the source and drain electrodes and the metal wiring comprise Al—Ni alloys.

10. The method of claim 8, wherein the source and drain electrodes and the metal wiring comprise Al—Ni alloys containing Ni of 10% or less.

11. The method of claim 8, wherein the pixel electrode comprises at least one material selected from a group consisting of indium tin oxide (ITO) and indium zinc oxide (IZO).

12. The method of claim 8, wherein the substrate comprises at least one material selected from a group consisting of glass and plastic.

13. The method of claim 8, wherein the organic layer comprises an emission layer, and at least one layer selected from a group consisting of a hole injecting layer, a hole transporting layer, a hole blocking layer, an electron transporting layer, and an electron injecting layer.

14. The method of claim 8, further comprising forming metal wiring on an insulating interlayer, wherein the metal wiring comprises a material having low resistance and an oxidation-reduction potential difference of about 0.3 or less with respect to the pixel electrode.
